(19) United States
(12) Patent Application Publication
(10) Pub. No.: US 2022/0300579 A1
(43) Pub. Date: Sep. 22, 2022

(54) ARITHMETIC PROCESSING DEVICE, COMPUTER-READABLE RECORDING MEDIUM STORING ARITHMETIC PROCESSING PROGRAM, AND ARITHMETIC PROCESSING METHOD

(71) Applicant: FUJITSU LIMITED, Kawasaki-shi (JP)

(72) Inventor: Toshihiro Shimizu, Kawasaki (JP)

(73) Assignee: FUJITSU LIMITED, Kawasaki-shi (JP)

(21) Appl. No.: 17/836,007

(22) Filed: Jun. 9, 2022

Related U.S. Application Data
(63) Continuation of application No. PCT/JP2020/001030, filed on Jan. 15, 2020.

(51) Int. Cl. G06F 17/16; G06F 7/487

(52) U.S. Cl. CPC G06F 17/16; G06F 7/4873

(57) ABSTRACT

An arithmetic processing device includes: a memory; and a processor coupled to the memory and configured to: store a minimum value of a loss function in a first two-dimensional array; and determine a break position in a quantization process on a basis of a second two-dimensional array that represents the break position in a case where the loss function is minimized in the first two-dimensional array.

### CROSS-REFERENCE TO RELATED APPLICATION

This application is a continuation application of International Application PCT/JP2020/001030 filed on Jan. 15, 2020 and designated the U.S., the entire contents of which are incorporated herein by reference.

### FIELD

The embodiment discussed herein is related to an arithmetic processing device, an arithmetic processing program, and an arithmetic processing method.

### BACKGROUND

A method of quantizing floating point to fixed point has been proposed. According to the quantization method, a position to be quantized is calculated from distribution of parameters to be quantized. The position to be quantized is determined on the basis of a value determined by a designer and absolute values of the parameters.

Japanese Laid-open Patent Publication No. 2008-77636 and Japanese Laid-open Patent Publication No. 08-339197 are disclosed as related art.

### SUMMARY

According to an aspect of the embodiments, an arithmetic processing device includes: a memory; and a processor coupled to the memory and configured to: store a minimum value of a loss function in a first two-dimensional array; and determine a break position in a quantization process on a basis of a second two-dimensional array that represents the break position in a case where the loss function is minimized in the first two-dimensional array.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram for explaining a quantization process of floating point to fixed point;

FIG. 2 is a diagram for explaining a loss function minimization process;

FIG. 3 is a diagram for explaining a break position searching process;

FIG. 4 is a block diagram schematically illustrating an exemplary hardware configuration of an arithmetic processing device according to an exemplary embodiment;

FIG. 5 is a block diagram schematically illustrating an exemplary software configuration of the arithmetic processing device illustrated in FIG. 4;

FIG. 6 is a diagram for explaining an outline of the quantization process in the arithmetic processing device illustrated in FIG. 4;

FIG. 7 is a diagram exemplifying a pseudocode of a break position search program in the arithmetic processing device illustrated in FIG. 4; and

FIG. 8 is a flowchart for explaining the break position searching process in the arithmetic processing device illustrated in FIG. 4.

### DESCRIPTION OF EMBODIMENTS

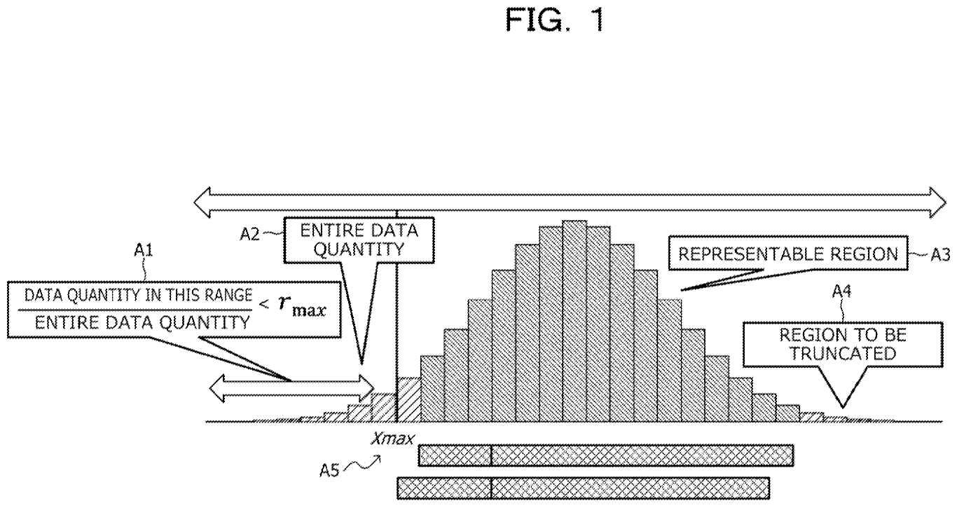

FIG. 1 is a diagram for explaining a quantization process of floating point to fixed point.

As indicated by a reference sign A1, the designer determines rₘₐₓ as a value indicating a region to be saturated (see reference sign A2; i.e., region with a large value and not being quantized). Furthermore, a representable region and a region to be truncated are also determined as indicated by reference signs A3 and A4, respectively.

As indicated by a reference sign A5, the maximum value xₘₐₓ of a set of input parameters excluding the region set by rₘₐₓ is found.

Next, the number of bits of an integer part that may be represented by xₘₐₓ is determined as n=ceil(log₂(xₘₐₓ)).

Then, from the number of bits after quantization set by the designer and the number of bits of the integer part n, it is determined that the number of bits of a decimal part m=bit width−n−1.

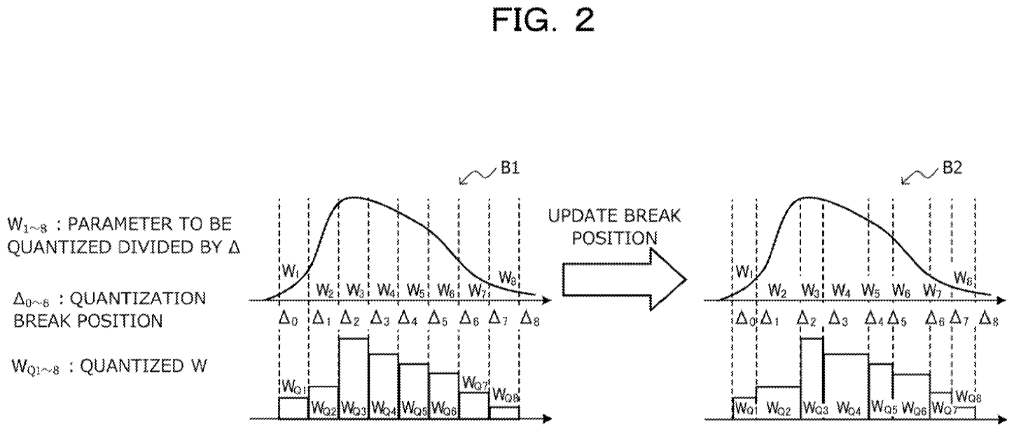

FIG. 2 is a diagram for explaining a loss function minimization process.

As indicated by a reference sign B1, in a case of quantizing a parameter to n=8, a parameter W to be quantized is divided into eight parts.

W₁ₜₒ₈ represent parameters to be quantized divided by Δ. Δ₀ₜₒ₈ represent quantization break positions. W_{Q1to8} represent quantized W.

First, the break position A1 that divides the smallest value is moved in a range from Δ₀ to Δ₂, and when a loss function Loss expressed by the following formula becomes smaller, the value of A1 is updated as indicated by a reference sign B2.

$$Loss = {\sum }_{i = 1}^{n} \frac{{‖ {w}_{{k}_{i}} ‖}_{L 1}^{2}}{{k}_{i}} \qquad [ Formula 1 ]$$

Next, the break position is sequentially moved from Δ₂ to Δ₇, and the break position is updated each time the loss function Loss becomes smaller.

Moreover, the update of Δ is repeatedly carried out until the update of the break position ends.

Then, parameters ki* and Wki* obtained from the determined break position are used to quantize the parameters on the basis of the quantization formula expressed by the following formula.

$${W}_{Qi} = \frac{{‖ {w}_{{k}_{i}} ‖}_{L 1}}{{k}_{i}^{*}} sign ( {w}_{{k}_{i}^{*}} ) \qquad [ Formula 2 ]$$

Note that n represents the number of parts to be quantized, and is a natural number of two or more. The number of elements of non-zero elements of Wi to be quantized is represented by kᵢ. Wₖᵢ represents a variable having the same number of elements as the variable Wi to be quantized in which k elements are extracted from the variable Wi in descending order of absolute value and the other elements are set to zero. The value of k that minimizes Loss is represented by kᵢ*.

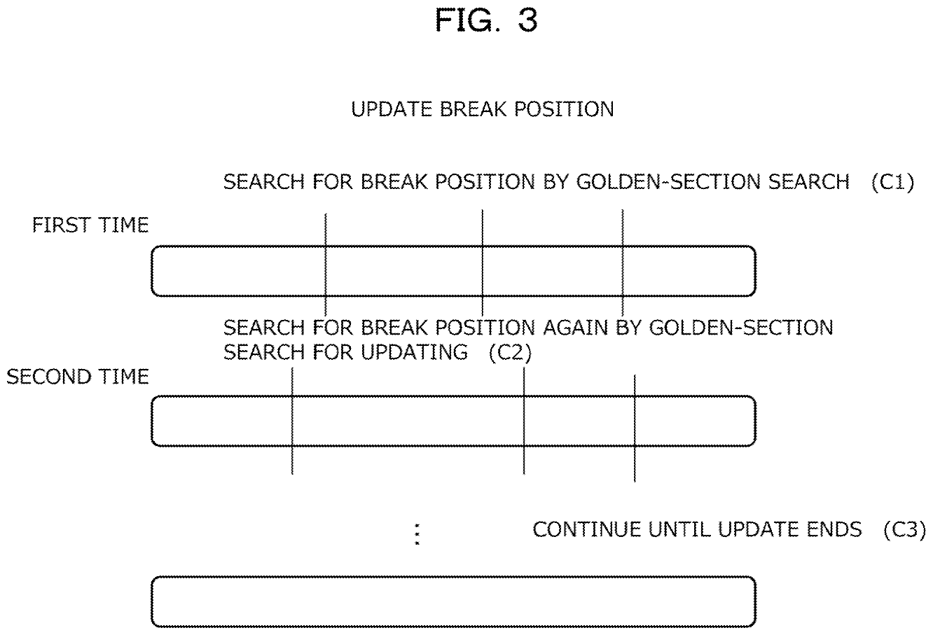

FIG. 3 is a diagram for explaining a break position searching process.

As indicated by a reference sign C1, in the first search, a break position is searched by the golden-section search. As indicated by a reference sign C2, in the second search, the break position is searched and updated again by the golden-section search. Then, as indicated by a reference sign C3, the search is continued until the update ends.

However, according to the quantization method described above, it may take a long time to search for the break position. Furthermore, the optimum solution for the quantization may not be obtained at times, and it may take a long time even when the optimum solution is obtained.

In one aspect, the techniques described herein aim to reduce the time needed for the quantization process.

Hereinafter, an embodiment will be described with reference to the drawings. Note that the embodiment to be described below is merely an example, and there is no intention to exclude application of various modifications and techniques not explicitly described in the embodiment. The present embodiment may be modified in a various ways to be implemented without departing from the spirit thereof.

Furthermore, each drawing is not intended to include only components illustrated in the drawing, and may include another function and the like.

Hereinafter, parts denoted by the same reference signs indicate similar parts in the drawings.

[A] Exemplary Embodiment

[A-1] Exemplary System Configuration

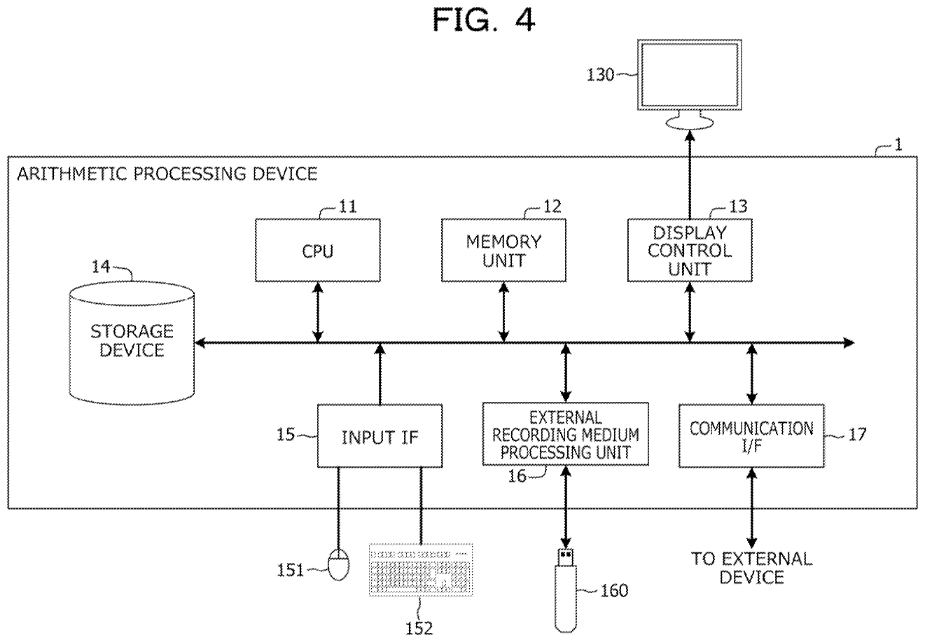

FIG. 4 is a block diagram schematically illustrating an exemplary hardware configuration of an arithmetic processing device 1 according to an exemplary embodiment.

As illustrated in FIG. 4, the arithmetic processing device 1 includes a central processing unit (CPU) 11, a memory unit 12, a display control unit 13, a storage device 14, an input interface (IF) 15, an external recording medium processing unit 16, and a communication IF 17.

The memory unit 12 is an example of a storage unit, which is, for example, a read only memory (ROM), a random access memory (RAM), or the like. Programs such as a basic input/output system (BIOS) may be written in the ROM of the memory unit 12. A software program of the memory unit 12 may be appropriately read and executed by the CPU 11. Furthermore, the RAM of the memory unit 12 may be used as a temporary recording memory or a working memory.

The display control unit 13 is connected to a display device 130, and controls the display device 130. The display device 130 is a liquid crystal display, an organic light-emitting diode (OLED) display, a cathode ray tube (CRT), an electronic paper display, or the like, and displays various kinds of information for an operator or the like. The display device 130 may be combined with an input device, and may be, for example, a touch panel.

The storage device 14 is a storage device having high input/output (I/O) performance, and for example, a hard disk drive (HDD), a solid state drive (SSD), or a storage class memory (SCM) may be used. The storage device 14 stores at least a part of entries in stream data. A plurality of the storage devices 14 may be provided depending on the number of extraction processes performed on the stream data.

The input IF 15 may be connected to an input device such as a mouse 151 and a keyboard 152, and may control the input device such as the mouse 151 and the keyboard 152. The mouse 151 and the keyboard 152 are exemplary input devices, and the operator performs various kinds of input operation through those input devices.

The external recording medium processing unit 16 is configured in such a manner that a recording medium 160 may be attached thereto. The external recording medium processing unit 16 is configured to be capable of reading information recorded in the recording medium 160 in a state where the recording medium 160 is attached thereto. In the present example, the recording medium 160 is portable. For example, the recording medium 160 is a flexible disk, an optical disk, a magnetic disk, a magneto-optical disk, a semiconductor memory, or the like.

The communication IF 17 is an interface for enabling communication with an external device.

The CPU 11 is a processor that performs various kinds of control and calculation, and implements various functions by executing an operating system (OS) and programs stored in the memory unit 12.

A device for controlling operation of the entire arithmetic processing device 1 is not limited to the CPU 11, and may be, for example, any one of an MPU, a DSP, an ASIC, a PLD, or an FPGA. Furthermore, the device for controlling the operation of the entire arithmetic processing device 1 may be a combination of two or more of the CPU, MPU, DSP, ASIC, PLD, and FPGA. Note that the MPU is an abbreviation for a micro processing unit, the DSP is an abbreviation for a digital signal processor, and the ASIC is an abbreviation for an application specific integrated circuit. Furthermore, the PLD is an abbreviation for a programmable logic device, and the FPGA is an abbreviation for a field-programmable gate array.

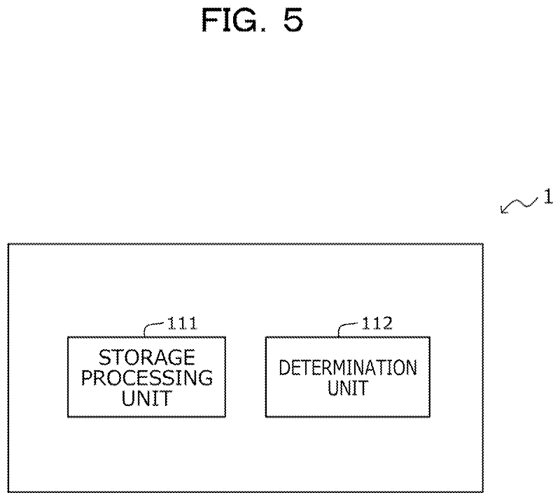

FIG. 5 is a block diagram schematically illustrating an exemplary software configuration of the arithmetic processing device 1 illustrated in FIG. 4.

As illustrated in FIG. 5, the arithmetic processing device 1 functions as a storage processing unit 111 and a determination unit 112.

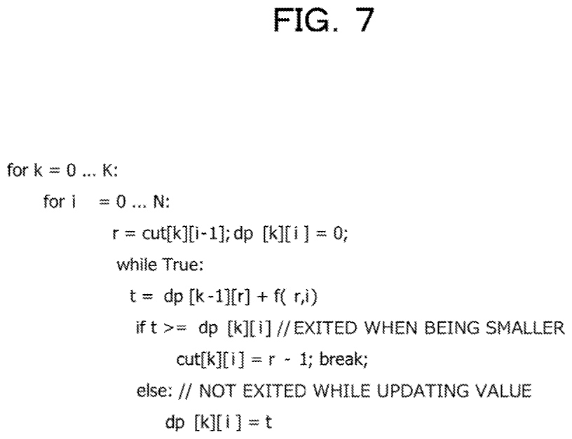

The storage processing unit 111 causes the memory unit 12 to store the minimum value of the loss function Loss expressed by the following formula. Note that details of the process in the storage processing unit 111 will be described later with reference to FIG. 7 and the like.

$$Loss = {\sum }_{i = 1}^{n} \frac{{‖ {w}_{{k}_{i}} ‖}_{L 1}^{2}}{{k}_{i}} \qquad [ Formula 3 ]$$

Note that n represents the number of parts to be quantized, and is a natural number of two or more. The number of elements of non-zero elements of Wi to be quantized is represented by kᵢ. Wₖᵢ represents a variable having the same number of elements as the variable Wi to be quantized in which k elements are extracted from the variable Wi in descending order of absolute value and the other elements are set to zero.

The determination unit 112 determines whether the minimum value of the loss function Loss stored by the storage processing unit 111 is updated. In a case where the minimum value of the loss function is updated, the determination unit 112 causes the storage processing unit 111 to store the new minimum value of the loss function Loss. On the other hand, in a case where the minimum value of the loss function Loss is not updated, the determination unit 112 determines a break position in a quantization process. Note that details of the process in the determination unit 112 will be described later with reference to FIG. 7 and the like.

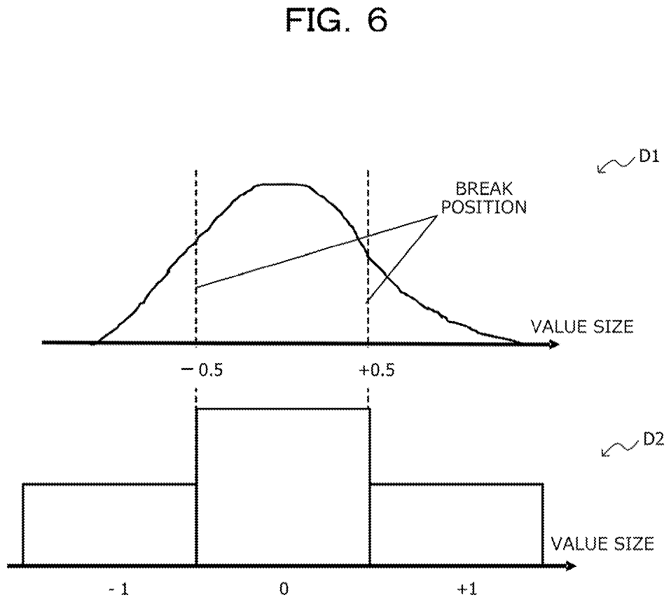

FIG. 6 is a diagram for explaining an outline of the quantization process in the arithmetic processing device 1 illustrated in FIG. 4.

In the example illustrated in FIG. 6, elements included in a tensor before quantization indicated by a reference sign D1 are made into a histogram at each break position according to a value size, thereby obtaining a value after quantization indicated by a reference sign D2. The break position indicates a threshold value for determining the value after quantization. Furthermore, the value after quantization indicates a representative value after the quantization.

When a two-variable function f(i, j) (0≤i≤j<n) holds f(i, l)+f(j, k)≥f(i, k)+f(j, l) for any i≤j≤≤k≤l, this function is said to “satisfy the Monge property”.

When the Monge property is used, it becomes possible to calculate the sum when a section [1, n) is divided into k chunks, which is Σ_{U[i,j)=[0,n)}f(i, j), at high speed.

Furthermore, when the Monge property is established, the most recent break position is monotonically increasing.

FIG. 7 is a diagram exemplifying a pseudocode of a break position search program in the arithmetic processing device 1 illustrated in FIG. 4.

In the pseudocode of the search program illustrated in FIG. 7, two-dimensional arrays dp and cut are prepared.

The array dp[k][i] stores the minimum value of the loss function Loss when indices up to index i are divided into k pieces. The minimum value of the loss function Loss may be stored in dp[k][i] by the storage processing unit 111 illustrated in FIG. 5.

The array cut[k][i] indicates the most recent break position in a case where the indices up to index i are divided into k pieces and the loss function Loss is minimized (i.e., index of the boundary between (k−1)-th and k-th pieces).

The array cut[k][i] is monotonically non-decreasing (i.e., monotonically increasing in a broad sense) for k and i. Due to the Monge property and convexity of the loss function Loss, it is sufficient if the break position to be searched to obtain dp[k][i] is from cut[k][i−1] to the position at which the value is not updated for the first time.

In the example illustrated in FIG. 7, the loop advances in the order of k and i. Then, the loop is not exited while the value stored in dp[k][i] is updated from the previous break position, and the loop is exited when the value stored in dp[k][i] becomes smaller than the previous value. The determination of whether or not to exit the loop may be made by the determination unit 112 illustrated in FIG. 5.

For example, the determination unit 112 determines the break position in the quantization process on the basis of cut[k][i] representing the break position in the case where the loss function Loss is minimized in dp[k][i]. Furthermore, the determination unit 112 determines the break position in a case where the value of cut[k][i] is not updated in comparison with the immediately preceding value.

Here, when the function f(i, j) is defined as f(i, j)=(aᵢ+aᵢ₊₁+ . . . +aⱼ₋₁)²/(j−i) for real numbers a₁, a₂, . . . , and an in which 0≤a₁≤a₂≤ . . . ≤aₙ is satisfied, this function f(i, j) becomes Monge. Hereinafter, the Monge property of the loss function Loss will be proved.

It is assumed that indices i, j, k, and l that satisfy i≤j and k≤l are given. At this time, it is sufficient if the following is established when the sum from i to j−1 is set as S₁, the number of pieces is set as n₁, the sum from j to k is set as S₂, the number of pieces is set as n₂, the sum from k+1 to l is set as S₃, and the number of pieces is set as n₃.

$$\frac{{S}_{2}^{2}}{{n}_{2}} + \frac{{( {S}_{1} + {S}_{2} + {S}_{3} )}^{2}}{{n}_{1} + {n}_{2} + {n}_{3}} \leq \frac{{( {S}_{1} + {S}_{2} )}^{2}}{{n}_{1} + {n}_{2}} + \frac{{( {S}_{2} + {S}_{3} )}^{2}}{{n}_{2} + {n}_{3}} \qquad [ Formula 4 ]$$

Here, average values A₁, A₂, and A₃ are set to A₁=S₁/n₁, A₂=S₂/n₂, and A₃=S₃/n₃, respectively, and A₂=A₁+d=A₃−e is further set (d, e≥0). A formula to be expressed at this time is as follows.

$${n}_{2} {A}_{2}^{2} + \frac{( \begin{matrix}( {n}_{1} + {n}_{2} + {n}_{3} ) {A}_{2} - \\ {n}_{1} d + {n}_{3} e\end{matrix} )}{{n}_{1} + {n}_{2} + {n}_{3}} \leq \frac{{( ( {n}_{1} + {n}_{2} ) {A}_{2} - {n}_{1} d )}^{2}}{{n}_{1} + {n}_{2}} + \frac{{( ( {n}_{2} + {n}_{3} ) {A}_{2} - {n}_{3} d )}^{2}}{{n}_{2} + {n}_{3}} , \qquad [ Formula 5 ]$$

$${n}_{2} {A}_{2}^{2} + ( {n}_{1} + {n}_{2} + {n}_{3} ) {A}_{2}^{2} + 2 ( - {n}_{1} d + {n}_{2} e ) {A}_{2} + \frac{{( - {n}_{1} d + {n}_{3} e )}^{2}}{{n}_{1} + {n}_{2} + {n}_{3}} \leq ( {n}_{1} + {n}_{2} ) {A}_{2}^{2} - 2 {n}_{1} {dA}_{2} + \frac{{n}_{1}^{2} {d}^{2}}{{n}_{1} + {n}_{2}} + ( {n}_{2} + {n}_{3} ) {A}_{2}^{2} - 2 {n}_{3} {eA}_{2} + \frac{{n}_{3}^{2} {e}^{2}}{{n}_{2} + {n}_{3}} ,$$

$$\frac{{( - {n}_{1} d + {n}_{3} e )}^{2}}{{n}_{1} + {n}_{2} + {n}_{3}} \leq \frac{{n}_{1}^{2} {d}^{2}}{{n}_{1} + {n}_{2}} + \frac{{n}_{3}^{2} {e}^{2}}{{n}_{2} + {n}_{3}} ,$$

$${n}_{1}^{2} {d}^{2} ( \frac{1}{{n}_{1} + {n}_{2}} - \frac{1}{{n}_{1} + {n}_{2} + {n}_{3}} ) + {n}_{3}^{2} {e}^{2} ( \frac{1}{{n}_{2} + {n}_{3}} - \frac{1}{{n}_{1} + {n}_{2} + {n}_{3}} ) + \frac{2 {n}_{1} {n}_{3} de}{{n}_{1} + {n}_{2} + {n}_{3}} \geq 0$$

The last formula clearly holds.

Furthermore, the function f(i, j) is a function convex upward with respect to i. Hereinafter, convexity of the loss function Loss will be proved.

The loss function is set as a function for j,

$$f ( i ) = \frac{{( {a}_{i} + {a}_{i + 1} + … + {a}_{j - i} )}^{2}}{j - i} \qquad [ Formula 6 ]$$

and f(j−1)−f(j)≥f(j)−f(j+1) is expressed. An inequality to be expressed is equivalent to f(j−1)+f(j+1)≥2f(j). Here, when S=aᵢ+aᵢ₊₁+ . . . +aⱼ₋₁, k=j−i, a=aⱼ₋₂, and b=aⱼ, a≤b holds from the monotonicity, and the formula to be expressed is as follows.

$$\frac{{( S - a )}^{2}}{k - 1} + \frac{{( S + b )}^{2}}{k + 1} \geq 2 \cdot \frac{{S}^{2}}{k} \qquad [ Formula 7 ]$$

Since (S+b)² is monotonically increasing with respect to b, it is sufficient to express it as b=a. Therefore, it is sufficient if the following formula is expressed.

$$\frac{{( S - a )}^{2}}{k - 1} + \frac{{( S + a )}^{2}}{k + 1} \geq 2 \cdot \frac{{S}^{2}}{k} \qquad [ Formula 8 ]$$

The following formula is derived by multiplying both sides by k(k−1)(k+1).

k(k+1)(S²−2Sa+a²)+k(k−1)(S²+2Sa+a²)≥2(k²−1)S₂

2S²−4kSa+2a²k²≥0

2(S−ak)²≥0 [Formula 9]

The last formula clearly holds.

[A-2] Exemplary Operation

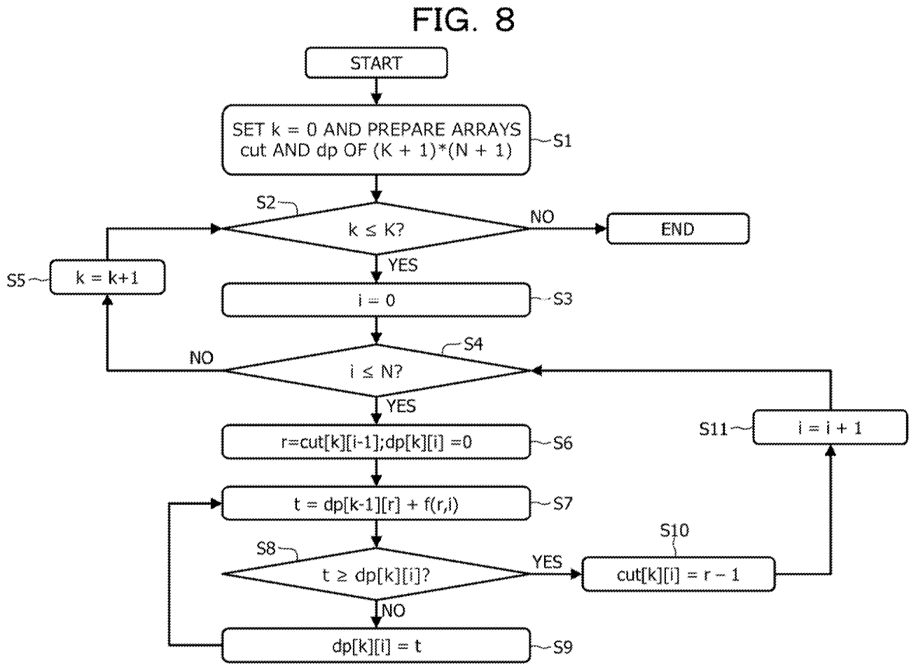

A break position searching process in the arithmetic processing device 1 according to the embodiment configured as described above will be described with reference to the flowchart (steps S1 to S11) illustrated in FIG. 8.

The determination unit 112 sets a variable k to zero, and prepares the arrays cut and dp of (K+1)*(N+1) (step S1).

The determination unit 112 determines whether k≤K holds (step S2).

If k>K (see No route in step S2), the break position searching process is terminated.

On the other hand, if k≤K (see Yes route in step S2), the determination unit 112 sets a variable i to zero (step S3).

The determination unit 112 determines whether i≤N holds (step S4).

If i>N (see No route in step S4), the determination unit 112 increments the variable k by one (step S5), and the process returns to step S2.

On the other hand, if i≤N (see Yes route in step S4), the storage processing unit 111 sets r to be cut[k][i−1], and stores zero in dp[k][i] (step S6).

The storage processing unit 111 sets t to be dp[k−1][r]+f(r, i) (step S7).

The determination unit 112 determines whether t dp[k][i] holds (step S8).

If t<dp[k][i] (see No route in step S8), the storage processing unit 111 stores t in dp[k][i] (step S9), and the process returns to step S7.

On the other hand, if t≥dp[k][i] (see Yes route in step S8), the storage processing unit 111 stores r−1 in cut[k][i] (step S10).

The determination unit 112 increments the variable i by one (step S11), and the process returns to step S4.

[A-3] Effects

According to the arithmetic processing device 1, the arithmetic processing program, and the arithmetic processing method according to the exemplary embodiment, for example, the following effects may be exerted.

The storage processing unit 111 stores the minimum value of the loss function in a first two-dimensional array dp[k][i]. The determination unit 112 determines a break position in the quantization process on the basis of a second two-dimensional array cut[k][i] representing a break position in a case where the loss function is minimized in the first two-dimensional array dp[k][i].

This makes it possible to shorten the time needed for the quantization process. For example, the time for searching the position at which floating point is quantized to fixed point is shortened, whereby it becomes possible to shorten the time for deep learning.

Furthermore, the determination unit 112 determines the break position in a case where the value of the second two-dimensional array cut[k][i] is not updated in comparison with the immediately preceding value. Furthermore, the determination unit 112 determines the break position by using the Monge property and the convexity of the loss function Loss. The first two-dimensional array dp[k][i] stores the minimum value of the loss function Loss when indices 0 to N (N is a natural number) are divided into k pieces for the distribution of quantization process targets. The second two-dimensional array cut[k][i] represents the break position in a case where the loss function Loss is minimized when the indices 0 to N are divided into k pieces for the distribution of the quantization process targets.

As a result, it becomes possible to efficiently carry out the break position search.

[B] Others

The disclosed technique is not limited to the embodiment described above, and various modifications may be made without departing from the spirit of the present embodiment. Each configuration and each process of the present embodiment may be selected or omitted as needed, or may be combined as appropriate.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An arithmetic processing device comprising:
a memory; and
a processor coupled to the memory and configured to:
store a minimum value of a loss function in a first two-dimensional array; and
determine a break position in a quantization process on a basis of a second two-dimensional array that represents the break position in a case where the loss function is minimized in the first two-dimensional array.

2. The arithmetic processing device according to claim 1, wherein
the processor determines the break position in a case where a value of the second two-dimensional array is not updated in comparison with an immediately preceding value.

3. The arithmetic processing device according to claim 1, wherein
the processor determines the break position using a Monge property and convexity of the loss function.

4. The arithmetic processing device according to claim 1, wherein
the first two-dimensional array stores the minimum value of the loss function when indices 0 to N (N is a natural number) are divided into k pieces for distribution of a target of the quantization process, and
the second two-dimensional array represents the break position in the case where the loss function is minimized when the indices 0 to N are divided into k pieces for the distribution of the target of the quantization process.

5. A non-transitory computer-readable recording medium storing an arithmetic processing program causing a computer to execute a processing, the processing comprising:
storing a minimum value of a loss function in a first two-dimensional array; and
determining a break position in a quantization process on a basis of a second two-dimensional array that represents the break position in a case where the loss function is minimized in the first two-dimensional array.

6. The non-transitory computer-readable recording medium according to claim 5, wherein
the determining includes determining the break position in a case where a value of the second two-dimensional array is not updated in comparison with an immediately preceding value.

7. The non-transitory computer-readable recording medium according to claim 5, wherein
the determining includes determining the break position using a Monge property and convexity of the loss function.

8. The non-transitory computer-readable recording medium according to claim 5, wherein
the first two-dimensional array stores the minimum value of the loss function when indices 0 to N (N is a natural number) are divided into k pieces for distribution of a target of the quantization process, and
the second two-dimensional array represents the break position in the case where the loss function is minimized when the indices 0 to N are divided into k pieces for the distribution of the target of the quantization process.

9. An arithmetic processing method comprising:
storing, by a computer, a minimum value of a loss function in a first two-dimensional array; and
determining a break position in a quantization process on a basis of a second two-dimensional array that represents the break position in a case where the loss function is minimized in the first two-dimensional array.

10. The arithmetic processing method according to claim 9, wherein
the determining includes determining the break position in a case where a value of the second two-dimensional array is not updated in comparison with an immediately preceding value.

11. The arithmetic processing method according to claim 9, wherein
the determining includes determining the break position using a Monge property and convexity of the loss function.

12. The arithmetic processing method according to claim 9, wherein
the first two-dimensional array stores the minimum value of the loss function when indices 0 to N (N is a natural number) are divided into k pieces for distribution of a target of the quantization process, and
the second two-dimensional array represents the break position in the case where the loss function is minimized when the indices 0 to N are divided into k pieces for the distribution of the target of the quantization process.
